(19) United States
(12) Patent Application Publication
(10) Pub. No.: US 2026/0330078 A1
(43) Pub. Date: Oct. 22, 2026

(54) COMPUTER-IMPLEMENTED GEOMETRY MONITORING METHOD

(71) Applicant: GAZTRANSPORT ET TECHNIGAZ, SAINT-REMY-LES-CHEVREUSE (FR)

(72) Inventors: Fabien PESQUET, SAINT-REMY-LES-CHEVREUSE (FR); Vincent FRAYSSE, SAINT-REMY-LES-CHEVREUSE (FR); Mikaël VOLUT, SAINT-REMY-LES-CHEVREUSE (FR); Christian HIRICOIU, SAINT-REMY-LES-CHEVREUSE (FR)

(21) Appl. No.: 19/111,251

(22) PCT Filed: Sep. 29, 2023
(86) PCT No.: PCT/EP2023/077177

§ 371 Date: Mar. 12, 2025

(30) Foreign Application Priority Data
Sep. 30, 2022 (FR) FR2210027

(51) Int. Cl. G06F 30/13

(52) U.S. Cl. CPC G06F 30/13

(57) ABSTRACT

In a computer-implemented geometry monitoring method, a plurality of measurements are provided that represent a measured position in a three-dimensional reference frame of a point located on a structure to be monitored. A cylindrical coordinate system is then determined that has a vertical axis parallel to an axis of the three-dimensional reference frame. Then, from the measurements, a plurality of discretisation points are calculated and then estimated positions of vertical edges of the structure to be monitored are calculated from the discretisation points. Further, from the estimated positions of the vertical edges, estimated positions are calculated of the medians each being a vertical section of the structure to be monitored. Finally, distances between diametrically opposite medians are compared with an acceptable range of diameter.

### TECHNICAL FIELD

The invention relates to a computer-implemented geometry monitoring method for monitoring the geometry of a structure, notably for monitoring the geometry of a supporting structure for a liquefied gas storage installation. The structure to be monitored can more particularly include a globally vertical wall of globally regular polygonal shape.

### TECHNOLOGICAL BACKGROUND

Known from the document U.S. Pat. No. 8,550,276 B2 is a liquefied gas storage installation comprising a vertical wall and a bottom wall in which said bottom wall includes a plurality of sectors that are images of one another by rotation and said bottom wall has the shape of a regular polygon each side of which corresponds to one of said sectors. Such a structure is advantageous in that it makes it possible to produce each sector using identical elements, which reduces the number of different elements to be employed. In particular, a great part of the bottom wall is produced with the aid of rectangular elements with identical dimensions.

Another liquefied gas storage installation of this type is known from the document WO 2011/048300 A1. In that document the installation also comprises a vertical wall and a bottom wall. The vertical wall includes a plurality of vertical panels. The bottom wall includes a plurality of rectangular parts distributed in sectors that are images of one another by rotation, respective edges of the rectangular parts of one of said sectors being parallel and perpendicular to one of said vertical panels. However, in contrast to the document U.S. Pat. No. 8,550,276 B2, the number of said vertical panels is twice the number of said sectors. The number of vertical panels is for example chosen equal to 56. As described in this document WO 2011/048300 A1, providing a large number of vertical panels, in particular a number of vertical panels twice the number of sectors, makes it possible to limit the quantity of material necessary to produce the supporting structure that has to receive the vertical wall and the bottom wall for the same storage volume.

In the above two documents the supporting structure is for example made of concrete.

### SUMMARY OF THE INVENTION

Some aspects of the invention stem from the observation that the supporting structure in practise has some dimensional differences compared to the regular polygon shape ideally intended. Such dimensional differences can make the construction of the installation difficult. It is therefore necessary for the dimensional differences not to exceed tolerances specified in advance. However, if the supporting structure has large dimensions manual verification that the supporting structure is within the specified tolerances can take a considerable time, during which construction of the installation cannot continue since it is not known whether the supporting structure conforms or not.

One idea behind the invention consists in providing a method implemented by a computer for monitoring the geometry of a structure on the basis of a plurality of measurements each representing a position measured in three dimensions of a point situated on the structure to be monitored.

The invention therefore proposes a computer-implemented geometry monitoring method comprising:
specifying a structure design representing for example a supporting structure for a liquefied gas storage installation, the structure design having geometric attributes and dimensional attributes, the geometric attributes including a number N of sides of a polygon, N being an integer greater than or equal to 3, the dimensional attributes including an acceptable range of diameters;
obtaining a plurality of first measurements each representing a measured position in a three-dimensional frame of reference of a point situated on a structure to be monitored;
determining a system of cylindrical coordinates having a vertical axis parallel to an axis of said three-dimensional frame of reference, said vertical axis having a position that minimizes a dispersion of said first measurements with respect to a radial coordinate of said system of cylindrical coordinates;
specifying first disjoint sectors of the space in the system of cylindrical coordinates, said first sectors being defined by azimuth coordinate increments and axial coordinate increments in said system of cylindrical coordinates;
calculating on the basis of the first measurements a plurality of first discretization points, each first discretization point representing a mean position of the structure to be monitored in one of said first sectors;
calculating on the basis of the first discretization points estimated positions of N vertical edges of the structure to be monitored;
calculating on the basis of the estimated positions of the N vertical edges estimated positions of N medians, each median being a median of the vertical panel of the structure to be monitored; and
comparing on the basis of the estimated positions of the N medians the distances between diametrically opposite medians and said acceptable range of diameters.

With the geometry monitoring method as defined hereinabove, the geometry of the supporting structure can be monitored on the basis of the first measurements in an automated manner, that is to say with no intervention by a user except to specify the design of the supporting structure. Monitoring the geometry is therefore easy even when the supporting structure has very large dimensions.

The number N represents a number of sides of a polygon having to serve as a directrix of a vertical wall of the structure to be monitored. If it conforms, the vertical wall will be close to an ideal shape consisting of N vertical panels separated by N vertical edges and forming a polygonal cylindrical surface having a regular polygon with N sides as directrix. In other words, the acceptable range of diameters can represent an acceptable distance between respective medians of two diametrically opposite vertical panels, which ensures sufficient resemblance to the ideal shape.

Embodiments of the geometry monitoring method can have one or more of the following features.

In accordance with one embodiment, said axis of said three-dimensional frame of reference is parallel to the direction of the terrestrial gravity field at the location of the structure to be monitored.

In accordance with one embodiment, the dimensional attributes further include an acceptable range of radii and the geometry monitoring method further comprises comparing the distances between said estimated positions of the N medians and said vertical axis with said acceptable range of radii.

In other words, the acceptable range of radii can represent an acceptable distance between the medians and said vertical axis, which ensures sufficient resemblance to the ideal shape.

In accordance with one embodiment, the dimensional attributes further include an acceptable range of panel widths and the geometry monitoring method further comprises comparing the distances between the estimated positions of two adjacent vertical edges with said acceptable range of panel widths.

In other words, the acceptable range of panel widths can represent an acceptable distance between two adjacent vertical edges, which ensures sufficient resemblance to the ideal shape.

In accordance with one embodiment, the dimensional attributes further include an acceptable range of edge non-verticality and the geometry monitoring method further comprises comparing distances perpendicular to the vertical axis of said system of cylindrical coordinates between endpoints of each vertical edge with said acceptable range of edge non-verticality.

In other words, the acceptable range of edge non-verticality can represent an acceptable distance perpendicular to a vertical axis of the structure to be monitored between two end points of a given vertical edge, which ensures sufficient resemblance to the ideal shape.

In accordance with one embodiment, the dimensional attributes further include an acceptable range of ovalization and the geometry monitoring method further comprises comparing a diameter difference between an inscribed larger circle of the vertical wall and a circumscribed smaller circle of the vertical wall of the structure to be monitored with said acceptable range of ovalization.

In other words, the acceptable range of edge non-verticality can represent an acceptable diameter difference between an inscribed larger circle on the vertical wall and a circumscribed smaller circle on the vertical wall, which ensures sufficient resemblance to the ideal shape.

In accordance with one embodiment, the dimensional attributes further include an acceptable range of local deformations of the vertical panels and the geometry monitoring method further comprises comparing local deformations of the structure to be monitored with said acceptable range of local deformations of the vertical panels.

In accordance with one embodiment, the dimensional attributes further include an acceptable range of non-verticality of the vertical panels and the geometry monitoring method further comprises:
selecting a subset of the first discretization points, in which subset the azimuth coordinates of the first discretization points are equal to one another;
determining the differences of radial coordinates between the first discretization points of the subsets; and
comparing the differences of radial coordinates with said acceptable range of non-verticality of the vertical panels.

In accordance with one embodiment, the radial coordinate differences are radial coordinate differences between a first discretization point of the subassembly that has the smallest vertical coordinate and the other first discretization points of the subassembly.

In accordance with one embodiment, the dimensional attributes further include an acceptable range of non-flatness of the vertical panels and the geometry monitoring method further includes:
on the basis of the estimated positions of the N vertical edges, selecting the first measurements corresponding to a vertical panel of the structure to be monitored;
calculating a vertical panel non-flatness parameter on the basis of the selected first measurements and comparing the vertical panel non-flatness parameter with said acceptable range of non-flatness of the vertical panels.

The vertical panel non-flatness parameter can be calculated for only one of or some of the vertical panels or preferably for all of the vertical panels of the structure to be monitored.

In accordance with one embodiment, the geometric attributes further include a plane bottom wall and the dimensional attributes further include an acceptable range of non-flatness of the bottom wall, and the geometry monitoring method further includes:
obtaining a plurality of second measurements each representing a position measured in said three-dimensional frame of reference of a point situated on a bottom wall of the structure to be monitored;
associating with the second measurements a system of cartesian coordinates, said system of cartesian coordinates having a first axis, a second axis and a third axis that are mutually perpendicular, the third axis coinciding with said vertical axis of said system of cylindrical coordinates;
specifying disjoint second sectors of the space in said system of cartesian coordinates, said second sectors being defined by increments of coordinates along the first axis and the second axis of said system of cartesian coordinates;
calculating on the basis of the second measurements a plurality of second discretization points, each second discretization point representing a mean position of the bottom wall of the structure to be monitored in one of said second sectors;
calculating a parameter of non-flatness of the bottom wall on the basis of the second discretization points and comparing the parameter of non-flatness of the bottom wall with said acceptable range of non-flatness of the bottom wall.

In accordance with one embodiment, the dimensional attributes further include an acceptable range of local deformations of the bottom wall and the geometry monitoring method further comprises comparing local deformations of the bottom wall of the structure to be monitored with said acceptable range of local deformations of the bottom wall.

In accordance with one embodiment, N is an even number and N is more particularly an even number between 8 and 56, even more particularly N=8 or N=56.

In accordance with one embodiment, the geometry monitoring method further comprises a generation step consisting in generating a visual representation of a result of at least one of or of all of or of some of said comparisons.

Such a visual representation can be displayed to a user or stored for subsequent display to a user, for example. This enables the user to have access to information usable to decide on corrective actions to be taken on the vertical wall and/or the bottom wall of the structure to be monitored.

In accordance with one embodiment, the geometry monitoring method further includes a display step consisting in displaying said visual representation on a display device for a user.

In accordance with one embodiment, the geometry monitoring method further includes the step of assigning a qualification of conformity to the structure to be monitored, the qualification of conformity being chosen between conform and non-conform.

In accordance with one embodiment, the plurality of first measurements come from acquisition of measurements by means of a measuring instrument in the structure to be monitored.

In accordance with one embodiment, the measuring instrument includes a laser detection and ranging device disposed in an internal space of the structure to be monitored.

In accordance with one embodiment, the invention further provides a computer program comprising instructions which, when the computer program is implemented by a computer, cause the computer to execute any embodiment of the geometry monitoring method described above.

In accordance with one embodiment, the invention further provides a computer-readable data medium on which said computer program is stored.

In accordance with one embodiment, the invention further provides a geometry monitoring device comprising at least one processor and at least one memory containing a computer program, in which device said at least one memory and the computer program are configured, with said at least one processor, to cause execution of any embodiment of the geometry monitoring method described above by the geometry monitoring device.

The measurements can be supplied to the computer program and to the geometry monitoring device in diverse ways. In accordance with one embodiment, the geometry monitoring device comprises the aforementioned measuring instrument, the measuring instrument being configured to store the plurality of first measurements and where applicable the plurality of second measurements in the memory of the geometry monitoring device. In accordance with another embodiment, the geometry monitoring device is configured to receive the plurality of first measurements and where applicable the plurality of second measurements on a data medium or via a network interface.

In accordance with one embodiment, the invention provides a method of monitoring conformity for monitoring the geometric conformity of a structure to be monitored, the conformity monitoring method comprising:
an acquisition step consisting in acquiring a plurality of measurements each representing a measured position in three dimensions of a point situated on the structure to be monitored; and
use of any of the embodiments of the geometry monitoring method described hereinabove.

In accordance with one embodiment, the acquisition step is carried out in a plurality of substeps, the laser detection and ranging device being disposed in each substep at a different location in the internal space of the structure to be monitored.

In accordance with one embodiment, during the acquisition step the measurements are associated with a measurement of the direction of the terrestrial gravity field at the location of the structure to be monitored.

In accordance with one embodiment, the structure to be monitored is a supporting structure for a liquefied gas storage installation.

In accordance with one embodiment, the structure to be monitored is made of concrete.

In accordance with one embodiment, the liquefied gas storage installation is intended to be installed on land. In this case, the structure to be monitored can be made of concrete.

In accordance with another embodiment, the liquefied gas storage installation is intended to be installed onboard a floating structure, such as a ship. In this case, the structure to be monitored can be a portion of a double hull of the floating structure.

In one embodiment, the liquefied gas is LNG, namely a mixture with a high content of methane stored at a temperature of approximately −162 °C at atmospheric pressure.

Other liquefied gases can also be envisaged, notably ethane, propane, butane or ethylene. Liquefied gases can also be stored under pressure, for example at a relative pressure between 2 and 20 bar, and in particular a relative pressure close to 2 bar. The tank can be made using various techniques, notably in the form of an integrated membrane tank or a self-supporting tank. The vertical wall of the tank can in particular be obtained by juxtaposition of vertical rows of plane insulating wall modules and vertical rows of corner insulating wall modules as described for example in the international application number PCT/EP2022/057845, published under the number WO 2022/200536 A1, or in the international application number PCT/EP2022/057848, published under the number WO 2022/200539 A1.

### BRIEF DESCRIPTION OF THE FIGURES

The invention will be better understood and other aims, details, features and advantages thereof will become more clearly apparent in the course of the following description of particular embodiments of the invention provided by way of non-limiting illustrative example only and with reference to the appended drawings.

FIG. 1 represents, in section perpendicular to its vertical axis, the shape of a polygonal supporting structure for a liquefied gas storage installation.

FIG. 2 depicts the principle of non-flatness of a vertical supporting panel of the supporting structure from FIG. 1.

FIG. 3 is a block schematic representing the steps of a method of monitoring the conformity of the supporting structure from FIG. 1.

FIG. 4 is a partial perspective view in the internal space of the supporting structure depicting a step of acquisition of measurements carried out in the supporting structure.

FIG. 5 is a schematic depicting by way of explanation a cartesian frame of reference in which the measurements obtained during the acquisition step are expressed.

FIG. 6 is a schematic analogous to FIG. 1 depicting various dimensional attributes of the supporting structure.

FIG. 7 is a schematic analogous to FIG. 1 depicting by way of explanation a parameter of ovalization of the supporting structure.

FIG. 8 is a schematic depicting by way of explanation an edge non-verticality parameter of the supporting structure.

FIG. 9A is a schematic depicting by way of explanation, in conjunction with FIG. 9B, the principle of a calculation step used to express the coordinates of the measurements obtained during the acquisition step in the FIG. 10 cylindrical frame of reference.

FIG. 9B is a schematic depicting by way of explanation, in conjunction with FIG. 9A, the principle of a calculation step used to express the coordinates of the measurements obtained during the acquisition step in the FIG. 10 cylindrical frame of reference.

FIG. 10 is a schematic depicting by way of explanation a cylindrical frame of reference used to express the coordinates of the measurements obtained during the acquisition step.

FIG. 11A is a schematic depicting by way of explanation, in conjunction with FIG. 11B and FIG. 11C, the principle of discretization of the measurements of the vertical supporting wall.

FIG. 11B is a schematic depicting by way of explanation, in conjunction with FIG. 11A and FIG. 11C, the principle of discretization of the measurements of the vertical supporting wall.

FIG. 11C is a schematic depicting by way of explanation, in conjunction with FIG. 11A and FIG. 11B, the principle of discretization of the measurements of the vertical supporting wall.

FIG. 12 is a schematic depicting by way of explanation the principle of calculation of estimated positions of vertical edges and medians of the vertical panels of the vertical supporting wall.

FIG. 13A is a schematic analogous to FIG. 1 and FIG. 6 depicting by way of explanation the principle of monitoring by calculating diverse parameters of the vertical supporting wall.

FIG. 13B is a schematic depicting by way of explanation the principle of monitoring by calculating local deformations of the vertical supporting wall.

FIG. 13C is a schematic depicting by way of explanation the principle of monitoring by calculating a verticality of the vertical supporting wall.

FIG. 14 is a schematic depicting by way of explanation the principle of discretization of the measurements of the bottom supporting wall seen in FIG. 4.

FIG. 15A is a graph depicting by way of explanation a non-flatness parameter of the bottom supporting wall.

FIG. 15B is a graph depicting by way of explanation another non-flatness parameter of the bottom supporting wall.

FIG. 16 is a schematic depicting by way of explanation the principle of monitoring by calculating local deformations of the bottom supporting wall.

FIG. 17 is a functional block schematic of a geometry monitoring device for implementing the conformity monitoring method from FIG. 3.

FIG. 18 is a schematic depicting by way of explanation the principle of monitoring by calculating a non-flatness parameter of the vertical supporting wall.

FIG. 19 is a schematic depicting by way of explanation marker lines usable for positioning insulating wall modules on the vertical supporting wall.

FIG. 20 is a schematic depicting by way of explanation marker lines that are usable for positioning insulating blocks on the bottom supporting wall.

### DESCRIPTION OF EMBODIMENTS

As mentioned hereinabove, the invention is directed to producing a liquefied gas storage installation, which bears the reference number 1 in the following description.

In accordance with a variant, the installation 1 is adapted to store a liquefied gas, in particular to store liquefied natural gas (LNG) at a temperature of approximately −162 °C and at atmospheric pressure, or other liquefied gases.

The supporting structure 10 is described first. The supporting structure 10 comprises at least one supporting wall that defines a cavity intended to receive the sealed tank 20. In one embodiment a main supporting wall 12 has an almost cylindrical geometry that surrounds the cavity. Such a main supporting wall 12 can further be closed by another supporting wall at one end at least in the directrix direction. In one embodiment, such a main supporting wall 12 can extend between a bottom supporting wall and a lid supporting wall.

The installation 1 can be designed to be situated on land. The main supporting wall 12 is then typically vertical, that is to say situated in a plane parallel to the direction of the acceleration due to gravity to within dimensional tolerances. The supporting structure 10 is for example made of concrete. In a manner that is not represented in the drawings, the bottom supporting wall can be situated at ground level or possibly below ground level. In a manner that is not represented in the drawings the supporting structure 10 comprises at the edge of the main supporting wall 12 opposite the bottom supporting wall a lid supporting wall closing the internal space 11 delimited by the bottom supporting wall and the vertical supporting wall 12. This lid supporting wall can support diverse equipment usable to feed the liquid product from or to this internal space 11. The bottom supporting wall and/or the lid supporting wall can for example be plane. However, other shapes are possible for the bottom supporting wall and the lid supporting wall, notably a spherical dome shape.

Alternatively, the installation 1 can be designed to be installed onboard a floating structure such as a ship. In this case the supporting structure 10 is a portion of a double hull of the floating structure. The main supporting wall 12 could possibly be non-vertical and even have a directrix in a direction perpendicular to the direction of the acceleration due to gravity when the floating structure is at rest.

There is more particularly considered hereinafter the case of an installation 1 situated on land where the main supporting wall 12 is vertical. Thus a vertical supporting wall 12 will be referred to hereinafter. It is nevertheless specified that the following description applies to any orientation of the main supporting wall 12 relative to the direction of the acceleration due to gravity.

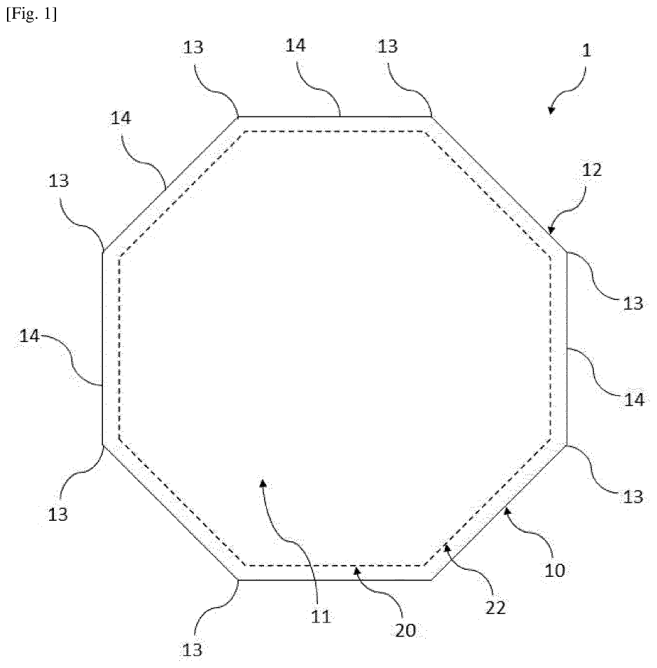

FIG. 1 is a schematic view of the supporting structure 10 in section perpendicular to a vertical axis 9 of the vertical supporting wall 12. The vertical supporting wall 12 is represented in solid line in FIG. 1. The vertical supporting wall 12 forms a polygonal cylindrical surface and is typically constructed using civil engineering techniques. Thus the vertical supporting wall 12 has vertical panels 14 separated from one another by edges 13.

The sealed tank 20 (represented in dashed line in FIG. 1) is intended to be installed in the internal space 11 of the supporting structure 10. The tank 20 includes a vertical peripheral wall 22 intended to face the vertical supporting wall 12. In a manner that is not represented in the drawings the tank 20 further includes a bottom wall facing the bottom supporting wall and a lid wall facing the lid supporting wall.

The vertical peripheral wall 22 can be formed of vertical rows of plane insulating wall modules and vertical rows of corner insulating wall modules as described for example in the international application number PCT/EP2022/057845, published under the number WO 2022/200536 A1, or in the international application number PCT/EP2022/057848, published under the number WO 2022/200539 A1. The bottom wall can include a plurality of angular sectors that are images of one another by rotation as described in WO 2022/200536 A1 or WO 2022/200539 A1.

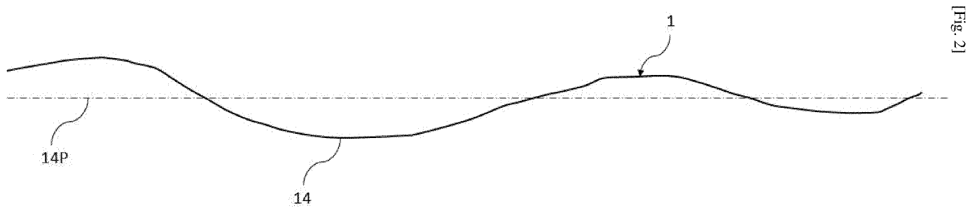

The positions and the orientations of the vertical panels 14 can exhibit dimensional deviations from an intended regular polygon shape. Furthermore, as represented schematically in FIG. 2, each vertical panel 14 can feature dimensional deviations relative to a plane ideal shape 14P. These dimensional deviations can for example be due to dimensional tolerances in a concrete structure. Such dimensional differences can make the construction of the installation 1 difficult. The dimensional differences must therefore not exceed tolerances specified in advance. However, if the supporting structure 10 has large dimensions verifying manually that the supporting structure 10 falls within the specified tolerances can take considerable time, during which construction of the installation 1 cannot continue because it is not known whether the supporting structure 10 is conform or not.

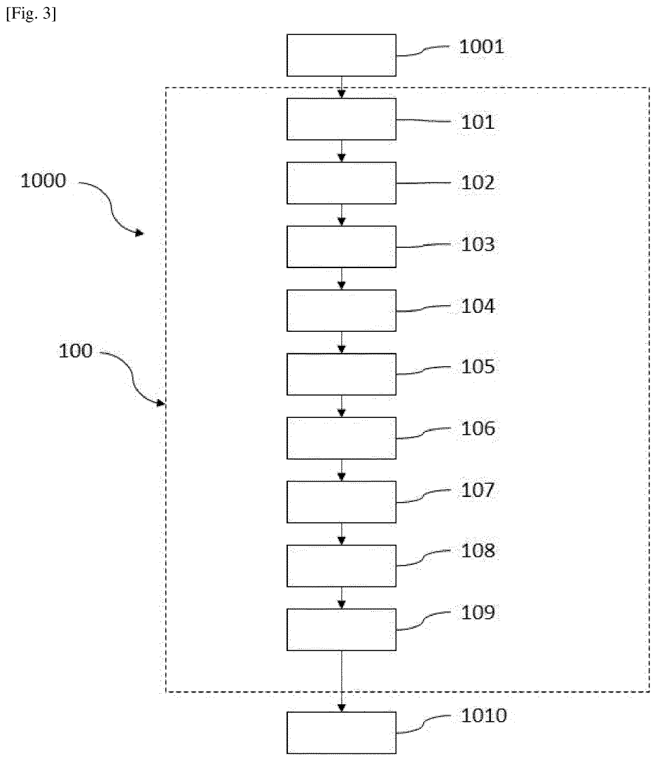

Described hereinafter with reference to FIGS. 3 to 16 is a conformity monitoring method 1000 (referred to for convenience hereinafter as “the method 1000”) for monitoring the geometric conformity of the supporting structure 1 relative to a given design.

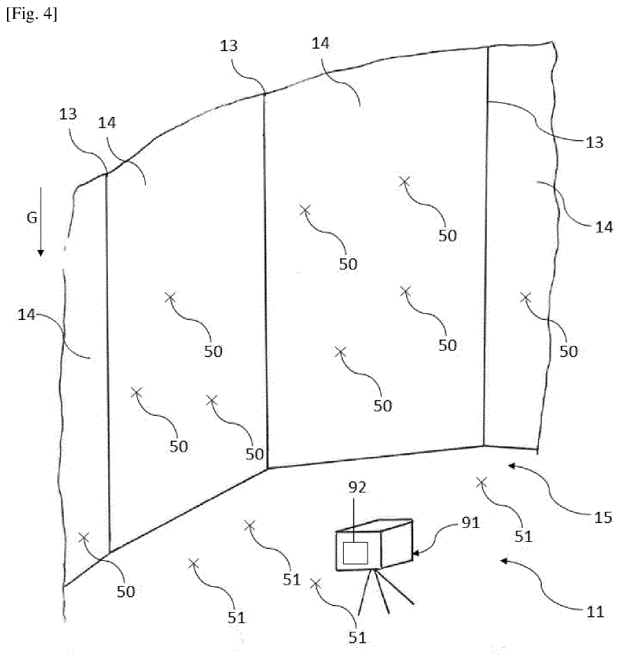

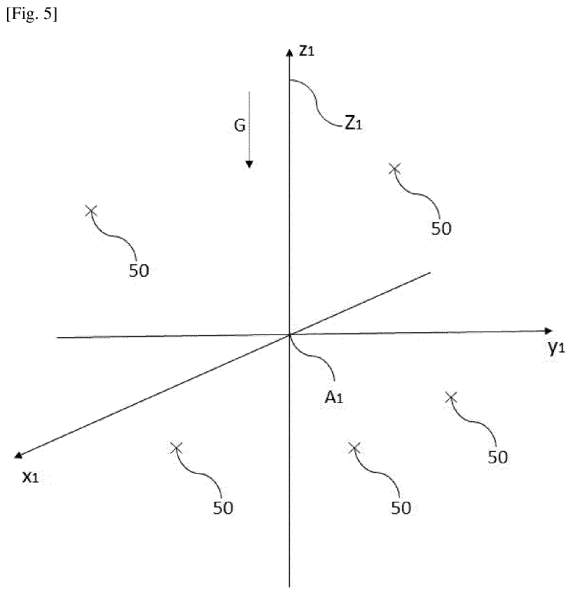

In a first step 1001 (cf. FIG. 3) of the method 1000, the supporting structure 1 having been constructed, a plurality of measurements 50 are acquired (cf. FIG. 4 and FIG. 5). Each measurement 50 represents a position measured in three dimensions of a point situated on the vertical supporting wall 12. In theory, each measurement 50 can be acquired by any appropriate detection and ranging technique. However, it is particularly advantageous to acquire the measurements 50 by means of a laser detection and ranging (lidar) device 91 disposed in the internal space 11. The operating principle of such a device 1 is known as such and is therefore not described in detail here.

In a very simple variant the acquisition step 1001 is carried out only once, with the device 91 disposed at a single point in the internal space 11.

However, it is preferable for the acquisition step 1001 to be carried out in a plurality of substeps, the device 91 being disposed at a different location in the internal space 11 in each substep. This can make it possible to achieve acquisition with satisfactory resolution over all of the vertical supporting wall 12. Of course, in this case the measurements 50 obtained in each substep are post-processed so that they are all expressed in the same spatial frame of reference.

In any event, following the acquisition step 1001, a large number of measurements 50 are available, expressed in the same spatial frame of reference. In accordance with one embodiment, as represented schematically in FIG. 5, the measurements 50 are expressed in the same orthogonal cartesian frame of reference (x₁, y₁, z₁), the origin A₁ of which is fixed arbitrarily. The third coordinate z₁ is preferably expressed along an axis precisely corresponding to the direction G (cf. FIG. 4 and FIG. 5) of the local terrestrial gravitational field, that is to say of the terrestrial gravitational field at the location of the supporting structure 10. The direction G of the local terrestrial gravity field can have been acquired during the step 1001 by means of an appropriate sensor 92, for example a sensor integrated into the device 91 (cf. FIG. 4). Although FIGS. 4 and 5 represent by way of explanation a few measurements 50, the result of the acquisition step 1001 can comprise a very large number of measurements 50, of the order of 10⁷ to 10⁹ measurements 50 in the case of a supporting structure 10 having internal dimensions of the order of 10¹ meters. As is known, the number of measurements 50 depends on the scanning parameters of the device 91 and on the number of substeps of the acquisition step 1001.

A geometry monitoring method 100 (hereinafter referred to as “the method 100”), the steps of which are described hereinafter follows the acquisition step 1001. In accordance with one embodiment the geometry monitoring method 100 is implemented by a computer executing an appropriate computer program. However, the method 100 can be implemented by any appropriate combination of hardware and software, including in a distributed information processing environment.

The method 100 comprises a first step 101 consisting in specifying a design to which the supporting structure 10 will be compared.

The number N of sides of the polygon to serve as a directrix for the vertical supporting wall 12 is specified in the design. N is an integer greater than or equal to 3.

For example, N is an even number. N is more particularly an even number between 8 and 56, for example. In one particular embodiment depicted in the drawings N is equal to 8. In another particular embodiment N is equal to 56.

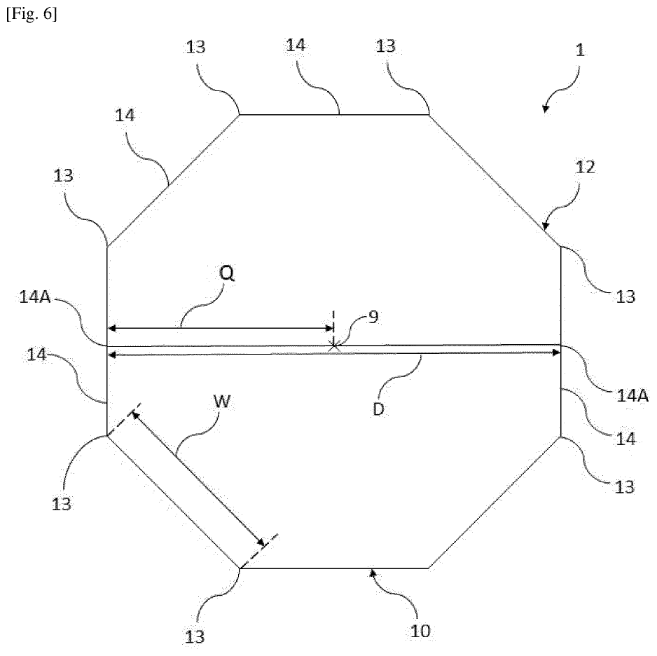

Hereinafter, the radius Q, the diameter D, the panel width W, the ovalization OV and the edge non-verticality NV are physical magnitudes of the supporting structure 10. The design has dimensional attributes, notably ranges of acceptable values for each of these magnitudes. FIGS. 6 to 8 depict these magnitudes in the supporting structure 10.

FIG. 6 depicts by way of explanation the radius Q and the diameter D. Like FIG. 1, FIG. 6 is a view of the supporting structure 10 in section perpendicular to a vertical axis of the vertical supporting wall 12. The vertical axis bears the reference number 9 in FIG. 6. Each vertical panel 14 can be associated with a median point 14A situated in the FIG. 6 section plane. The radius Q is the distance in this section plane between the median point 14A and the vertical axis 9. The diameter D is the distance between the median points 14A of two diametrically opposite vertical panels 14.

FIG. 6 also depicts by way of explanation the panel width W. Considering a vertical panel 14, the panel width W associated with that vertical panel is the distance in the FIG. 6 section plane between the two vertical edges 13 delimiting the panel 14.

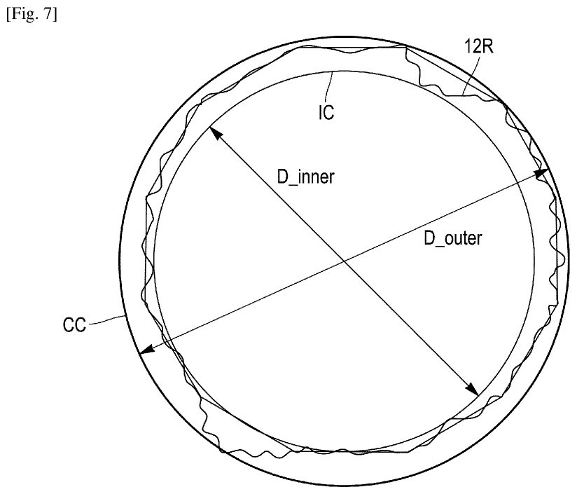

FIG. 7 depicts by way of explanation the ovalization OV. Like FIG. 1 and FIG. 6, FIG. 7 is a view of the supporting structure 10 in section perpendicular to the vertical axis 9. Given a real contour 12R of the vertical supporting wall 12 in the FIG. 7 section plane, an inscribed larger circle IC in the real contour 12R and a circumscribed smaller circle CC in the real contour 12R can be defined. The inscribed larger circle IC has a diameter D_inner and the circumscribed smaller circle CC has a diameter D_outer. The ovalization OV is the difference between these two diameters, that is to say OV=D_outer−D_inner.

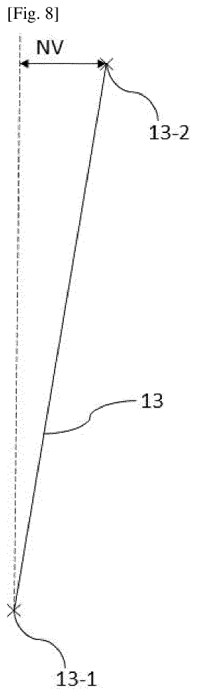

FIG. 8 depicts by way of explanation the edge non-verticality NV. FIG. 8 is a schematic front view of an edge 13 separating two vertical panels 14 (not represented in FIG. 8). Given two end points 13-1 and 13-2 of the edge 13, the edge non-verticality NV is the absolute value of the distance perpendicular to the vertical axis 9 between the end points 13-1 and 13-2. The vertical supporting wall 12 end points 13-1 and 13-2 can be points on the edge 13 in two spaced reference planes parallel to the vertical axis 9.

The acceptable range of each of the magnitudes mentioned hereinabove can be specified in the form of a range of numerical values. Alternatively, an acceptable range can be specified in the form of a reference value V and a tolerance T with respect to that reference value V; the acceptable range is then the interval between V−T and V+T, this interval being open, closed or semi-closed, depending on the requirements of the implementation. When the reference value V is a non-zero value, the tolerance T can notably be specified in the form of a percentage of V. Where the diameter D, the radius Q and the panel width W are concerned, the reference value is a non-zero value specified in advance given the required proportions and dimensions of the supporting structure 10, and the tolerances are non-zero values specified in advance given acceptable tolerances for these required proportions and dimensions of the supporting structure 10. Where the ovalization OV and the edge non-verticality NV are concerned, the reference value is zero and the tolerance is a non-zero value specified in advance.

The geometric attributes and/or the dimensional attributes of the design can be specified by a user, for example by means of a computer-implemented user interface. Alternatively, the design can also have been specified in advance in the form of a file of parameters, possibly editable by the user. The acceptable ranges are advantageously editable by the user. In particular, when the tolerances are specified in the form of a percentage as mentioned hereinabove, the percentage is advantageously editable by the user. This enables the user to perform tighter or looser monitoring of the conformity of the supporting structure 10 to be modified, by modifying the percentage. Looser monitoring will use a lower percentage, for example advantageously 10%, 5% or 3%, which amounts to accepting a difference relative to the reference value of 10% or less, 5% or less, or 3% or less. Tighter monitoring will use a higher percentage, for example advantageously 15%, 20% or 25%, which amounts to accepting a difference relative to the reference value of 15% or less, 20% or less, or 25% or less. In any event, for each of the magnitudes mentioned hereinabove the acceptable range specifies the difference that will be accepted between the design and the supporting structure 10 to be monitored.

The method 100 further comprises a step 102 in which the measurements 50 of the supporting structure 10 to be monitored described hereinabove are supplied. In concrete terms, the measurements 50 are provided in the form of a computer file on a data medium or via a network interface. For example, the computer file is supplied in the .pts file format well known in the field of laser detection and ranging devices.

The method 100 further comprises a step 103 in which a system of cylindrical coordinates (r, θ, z) is determined from the measurement 50.

As is known, defining a system of cylindrical coordinates assumes definition of a vertical axis along which a coordinate z is measured and polar coordinates r, θ perpendicular to that vertical axis. Thus in implementing step 103 it is necessary first to define a vertical axis along which the coordinate z is measured.

To this end, the cartesian orthogonal frame of reference (x₁, y₁, z₁) mentioned hereinabove in which the measurements 50 are expressed is defined so that its vertical axis Z₁ is parallel to the direction G of the local terrestrial gravitational field. The vertical axis 19 of the system of cylindrical coordinates is chosen to be parallel to the vertical axis Z₁. Clearly the vertical axis 19 is therefore parallel or virtually parallel to the vertical axis 9 of the supporting structure 10 to be monitored.

Furthermore, the position of the vertical axis 19 minimizes dispersion of the radial coordinate r of the measurements 50. Clearly the vertical axis 19 is therefore very close to the vertical axis 9 of the supporting structure 10 to be monitored. Furthermore, as described in detail hereinafter, the edges 13 are therefore precisely the locations at which maxima of the radial coordinate r exist.

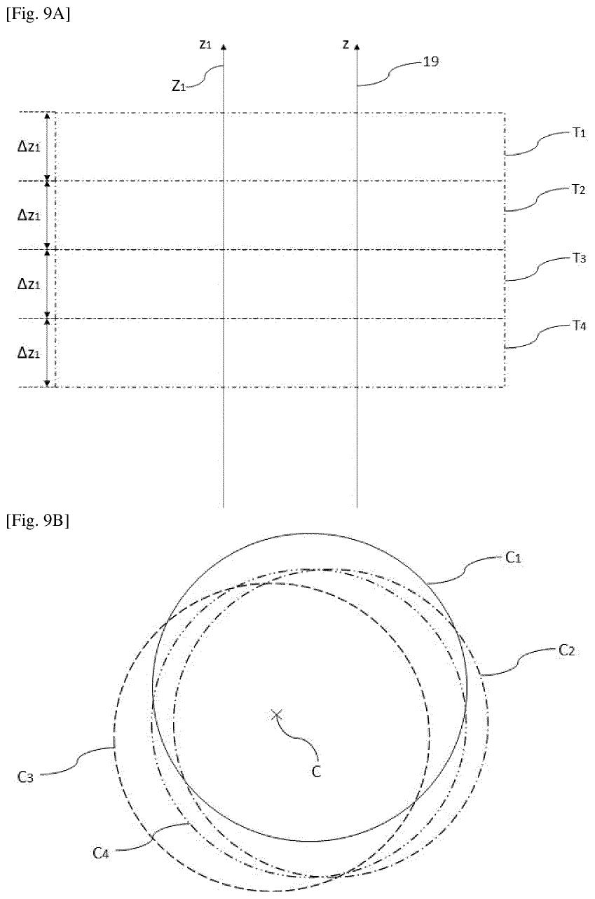

Various mathematical methods are appropriate for finding a position of the vertical axis 19 that minimizes dispersion in the radial coordinate r of the measurements 50. In a simple embodiment represented schematically in FIG. 9A, a plurality of (here four) subsets T₁, T₂, T₃, T₄ of measurements 50 are selected, the subsets T₁, T₂, T₃, T₄ being defined by increments Δz₁ of vertical coordinates z₁, and for each subset T₁, T₂, T₃, T₄ an associated interpolation circle C₁, C₂, C₃, C₄ (cf. FIG. 9B) is calculated perpendicular to the vertical axis Z₁, after which a barycenter C of the centers of the circles C₁, C₂, C₃, C₄is calculated. The vertical axis 19 is defined as passing through this barycenter C and being parallel to the vertical axis Z₁.

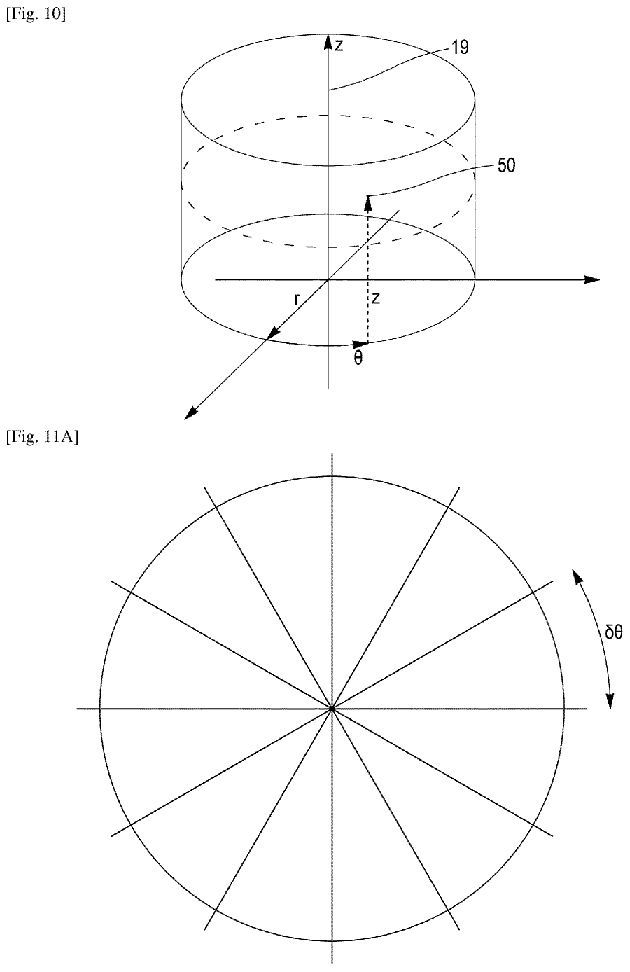

Thereafter, the cartesian coordinates of the measurements 50 in the cartesian frame of reference (x₁, y₁, z₁) (cf. FIG. 5) are converted by calculation into cylindrical coordinates (r, θ, z) (cf. FIG. 10) using known mathematical relationships. The direction in which θ=0° can be chosen arbitrarily or chosen as a function of the position of a marker on one of the panels 14 or a preselected structural element on one of the panels 14. The positive sense of the vertical axis 19 is preferably chosen as opposite to the sense of the acceleration due to terrestrial gravity.

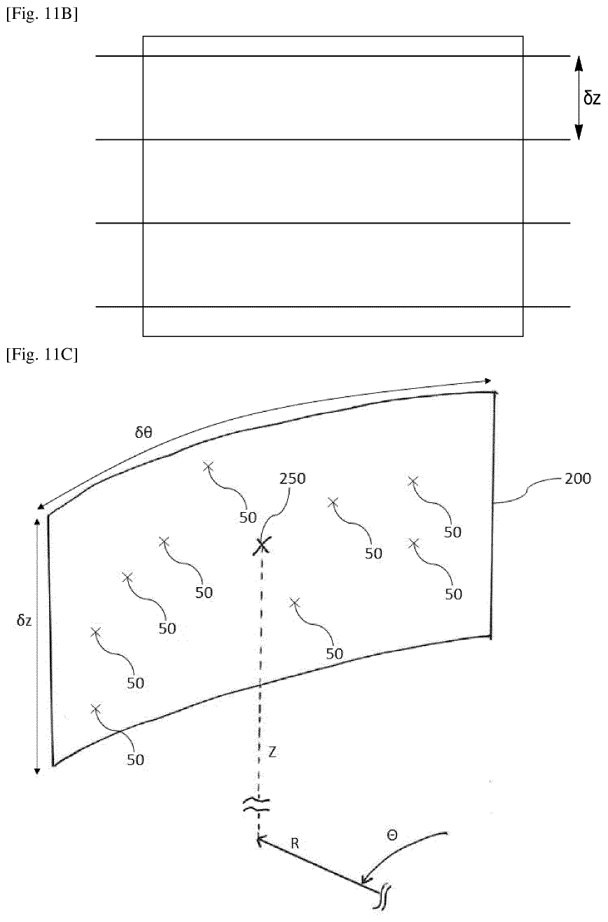

The method 100 further comprises a step 104 in which are specified disjoint sectors 200 (cf. FIG. 11C) of the space in the system of cylindrical coordinates (r, θ, z). In concrete terms, these sectors 200 are defined by an increment δθ of coordinates θ (cf. FIG. 11A and FIG. 11C) and by an increment δz of coordinates z (cf. FIG. 11B and FIG. 11C).

Like the numerical values of the design described hereinabove with reference to step 101, the increments δθ and δz can be specified by a user, for example by means of a computer-implemented user interface. Alternatively, the design can also have been specified in advance in the form of a file of parameters, possibly editable by the user. The increments δθ and δz can be specified a priori thanks to a knowledge of the reference value Q₀ of the radius Q described hereinabove. For example, the increments δθ and δz can be specified so that a surface area of the vertical support wall 12 included in a given sector 200 is between 1 cm² and 10 cm².

The method 100 further comprises a step 105 in which discretization points 250 are calculated on the basis of the measurements 50, one of which points is represented by way of illustration in FIG. 11C. In more concrete terms, a discretization point 250 is calculated for each sector 200. Each sector 200 is associated with a range of cylindrical coordinates {Θ±δθ/2, Z±δz/2}. The discretization point 250 is the center of the sector 200. Its cylindrical coordinates are {R, Θ, Z}, where R is the mean of the coordinates r of all the measurements 50 situated in the sector 200.

The method 100 further comprises a step 106 in which estimated positions 300 of the N vertical edges 13 are calculated on the basis of the discretization points 250 calculated in step 105.

This calculation can be effected in very many ways. This calculation advantageously consists in looking for a set of N vertical straight line segments 13 thanks to the known reference value W₀ of the panel width W described hereinabove, spaced by approximately W₀ and the positions of which correspond to N local maxima of r.

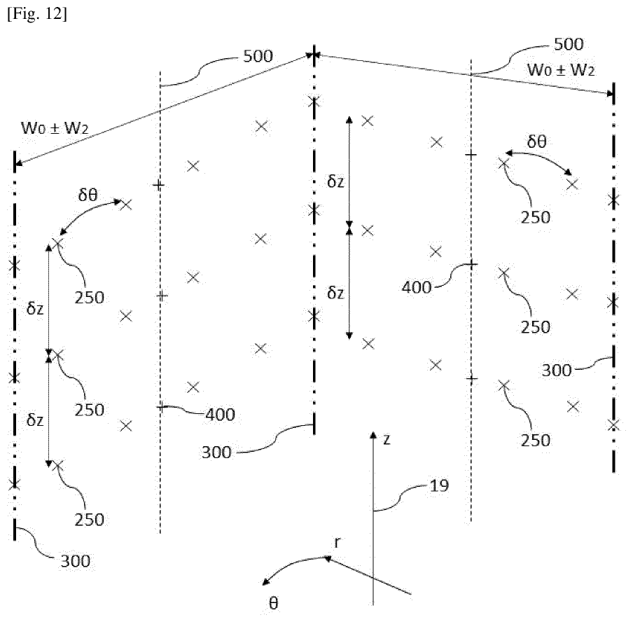

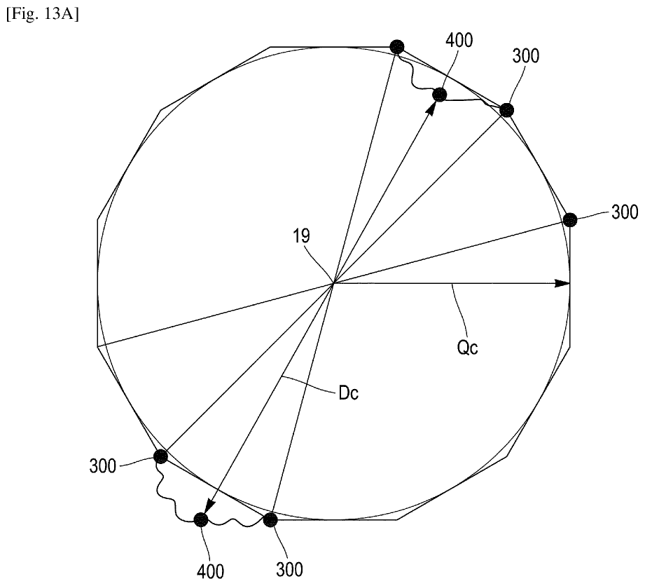

The principle of such calculation will be understood better by referring to FIG. 12. In this figure there have been represented very schematically in the system of cylindrical coordinates (r, θ, z) a few of the discretization points 250 calculated in step 105, together with estimated positions 300 of the N vertical edges 13. The calculation consists in looking for a position of a set of N vertical straight line segments 300 subject to the following two constraints:
(i) each of the N straight line segments 300 is sufficiently near local maxima of r as a function of θ;
(ii) each straight line segment 300 is separated from an adjacent straight line segment 300 by a distance perpendicular to the vertical axis 19 of the system of cylindrical coordinates (r, θ, z) that is included in the range [W₀−W₂; W₀+W₂], where W₂ is a non-zero value.

It will be noted that W₂ is not necessarily equal to the value of the tolerance for W₀; to the contrary, W₂ can for example be chosen as equal to 2.5 times or 3.0 times that tolerance. The criterion (ii) can then make it possible to prevent a local pressure reduction on one of the vertical panels 14 being considered wrongly as a vertical edge 13. It will also be noted that the straight line segments 300 do not necessarily pass through discretization points 250, and can even not pass through any discretization point 250.

In any event, following step 106 estimated positions 300 of the vertical edges 13 are available. The method 100 further comprises a step 107 in which are calculated, on the basis of the estimated positions 300 of the vertical edges 13, estimated positions of N medians 500 of the vertical panels 14 of the supporting structure 10 to be monitored. In one embodiment, still referring to FIG. 12, this step 107 comprises calculating the positions of points 400 that are perpendicularly equidistant from the vertical axis 19 of the straight line segments 300. To simplify the calculation, the positions of the points 400 are preferably calculated at the same coordinate z as the discretization points 250. If it proves that this coordinate z of a point 400 does not coincide with a discretization point 250, the coordinate r of that point 400 is calculated by interpolation (for example by linear interpolation) on the basis of the coordinates of adjacent discretization points 250. The positions of the medians 500 are then calculated by interpolation on the basis of the positions of the points 400.

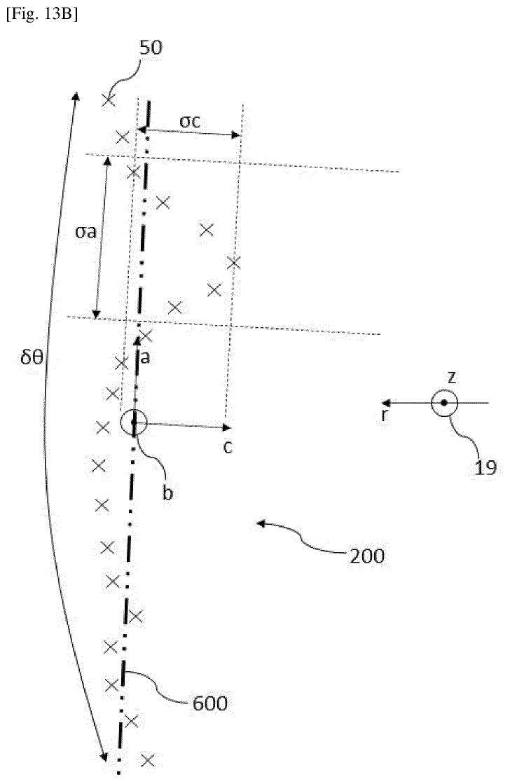

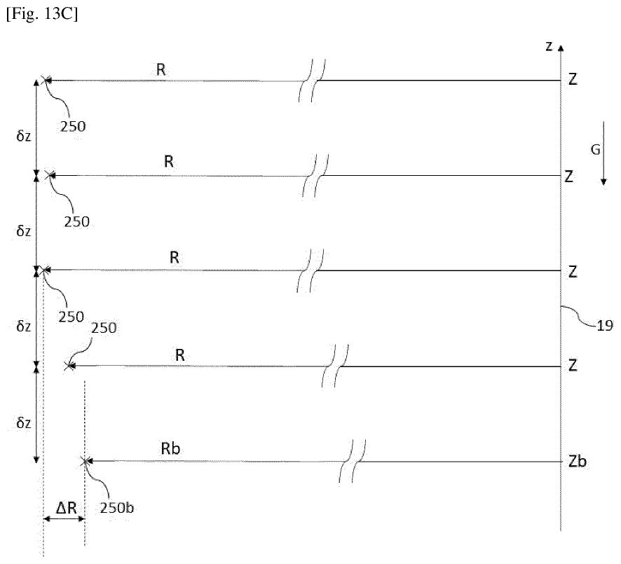

The method 100 further comprises a step 108 in which, on the basis of the estimated positions of the medians calculated in step 107, distances are compared between diametrically opposite medians and the acceptable range of diameters D. Referring to FIG. 13A, this calculation can consist in calculating a distance D_{c} between two diametrically opposite points 400 situated in the same vertical plane (in other words situated at the same coordinate z), and monitoring this distance D_{c} in the acceptable range of diameters D.

Some or all of the comparisons listed hereinafter can equally well be effected in step 108.

Notably, referring to FIG. 13A, from estimated positions of the medians 500 calculated in step 107, and more specifically positions of the points 400, the distances Q_{c} between the vertical axis 19 and each of the N points 400 are compared with the acceptable range of radii Q.

Furthermore, still referring to FIG. 13A, the distances are calculated between the estimated positions 300 of the vertical edges 13 calculated in step 106 and those distances are compared with the acceptable range of panel widths W.

Furthermore, returning to FIG. 7, the positions and the diameters D_inner and D_outer of the inscribed larger circle IC and the circumscribed smaller circle CC are calculated, the ovalization value OV=D_outer−D_inner is calculated, and that calculated value is compared with the acceptable range of ovalization OV.

Furthermore, on the basis of the straight lines 300 calculated in step 106, the positions of two end points situated on the straight line segments 300 are calculated, the absolute value of NV perpendicular to the vertical axis 19 between these two end points is calculated, and NV is compared with the acceptable range of edge non-verticality.

Furthermore, local deformations of the vertical supporting panels 14 are compared with an acceptable range of local deformations of the vertical supporting panels 14 specified beforehand in step 101. This comparison is described in more detail with reference to FIG. 13B. A local interpolation plane 600 is calculated for a given sector 200 on the basis of all the measurements 50 included in this sector 200. This plane 600 is then associated with an orthogonal local cartesian frame of reference (a, b, c) that is defined as follows: the axis (c) is perpendicular to the plane 600, the axis (b) is parallel to the vertical axis 19 of the system of cylindrical coordinates (r, θ, z), and the axis (a) is orthogonal to the axes (b) and (c). The coordinates of the measurements 50 are then expressed in this local cartesian frame of reference (a, b, c) using known mathematical relations.

Thereafter, a value σa having been specified, the sector 200 is searched for the measurements 50 the coordinates of which (a) are included in an interval of width σa (cf. FIG. 13B); among these measurements 50, the two measurements 50 farthest from the plane 600 perpendicularly to the axis (c) are looked for, one in the positive direction of the axis (c) and the other in the negative direction of the axis (c); the difference σc between the coordinates along the axis (c) of these two measurements 50 is calculated; this difference σc is compared with the acceptable range of local deformations. This process is repeated until the sector 200 is exhausted, the interval of width σa being offset each time by a fixed increment; in other words, the interval of width σa is used as a sliding window, which can be of any width along the axis (b) of the local Cartesian reference (a, b, c). The foregoing operations are repeated for each of the sectors 200.

Furthermore, a radial coordinate difference is calculated between all the discretization points 250 having the same azimuth coordinate Θ and the lowest of them and this difference is compared with an acceptable range of non-verticality of the vertical supporting panels 14 that was previously specified in step 101. This comparison is described in more detail with reference to FIG. 13C. Among all the discretization points 250 having a given coordinate Θ, the radial coordinate Rb of the discretization point 250b that has the smallest coordinate Zb along the vertical axis 19 is obtained. Thereafter the radial coordinate difference ΔR=R−Rb is calculated for each discretization point 250 having the same coordinate Θ and ΔR is compared with the acceptable range of non-verticality of the vertical support panels 14. The foregoing operations are repeated for each coordinate Θ between 0 and 360°.

Alternatively, the difference ΔR can be calculated for some discretization points 250 having a given coordinate Θ. Alternatively, the difference ΔR can be calculated for only some discretization points 250 having a coordinate Z included in one or more given ranges. This can enable evaluation of the non-verticality of the vertical supporting panels 14 over particular zones thereof and/or prevent the evaluation of the non-verticality of the vertical supporting panels 14 from being falsified by the connection between the bottom supporting wall 15 and the vertical supporting panels 14, especially when this connection takes the form of a chamfer. Alternatively, the radial coordinate difference ΔR can be calculated with the radial coordinate of a discretization point 250 other than the discretization point 250b.

The method 100 can optionally comprise a step 109 of generating at least one visual representation of the conformity of the supporting structure from the results of the monitoring effected in step 108. For example, this visual representation can comprise or consist of graphs indicating by means of colors the regions of the vertical supporting wall 12 in which the various parameters calculated in step 108 do not fall within the acceptable ranges specified in step 101. To this end, and more concretely, for each sector 200 of the vertical supporting wall 12 and for each parameter calculated in step 108 a Boolean variable is calculated and takes the value NO (meaning non-conform) if the parameter does not fall within the associated acceptable range specified in step 101 or YES (meaning conform) otherwise. Additionally or alternatively, the visual representation can comprise or consist of graphs indicating by means of colors the various parameters calculated in step 108 on a graphical representation of the vertical supporting wall 12.

In a step 1010 of the method 1000 the visual representation or representations generated in step 109 can be displayed to a user, which provides the latter with information usable to decide on corrective actions to be undertaken on the vertical supporting wall 12. The method can also lead to generating a conformity qualification chosen from conform and non-conform, for example a Boolean variable. In one example, the Boolean variable can take the value YES (meaning conform) if a percentage of non-conform sectors 200 of the vertical supporting wall 12 is less than a predetermined percentage and take the value NO (meaning non-conform) otherwise.

Until now there has been described only monitoring the geometry of the vertical supporting wall 12. Nevertheless, as mentioned above, the supporting structure 10 can equally include a bottom supporting wall. There is described hereinafter a variant of the method 100 that is applicable when this bottom supporting wall 15 (cf. FIG. 4) is plane.

In this variant, in the acquisition step 1001 the device 91 further acquires a plurality of measurements 51 (cf. FIG. 4) in which each measurement 51 represents a position measured in three-dimensions of a point situated on the bottom supporting wall 15 of the supporting structure 10 to be monitored. In step 102 these measurements 51 are provided at the same time as the measurement 50.

The measurements 51 are expressed in the same orthogonal cartesian frame of reference (x₁, y₁, z₁) as the measurements 50.

In step 103 the cartesian coordinates of the measurements 51 in the cartesian frame of reference (x₁, y₁, z₁) (cf. FIG. 5) are converted by calculation in accordance with known mathematical relations into cartesian coordinates in a system of cartesian coordinates (x, y, z) the vertical axis z of which coincides with the vertical axis 19 of the system of cylindrical coordinates of the measurements 50.

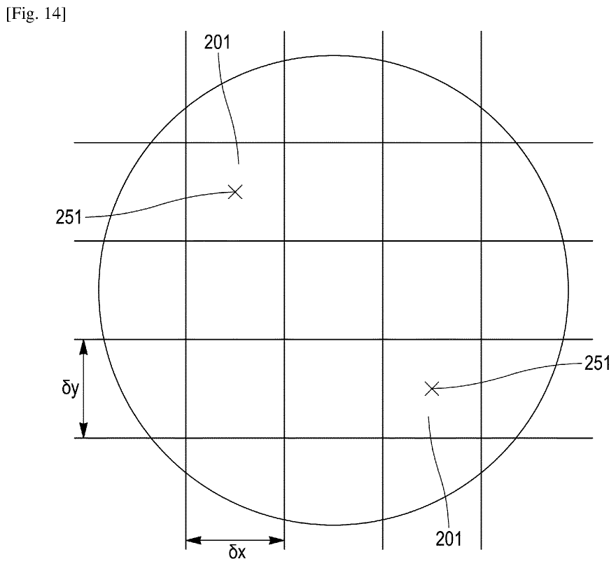

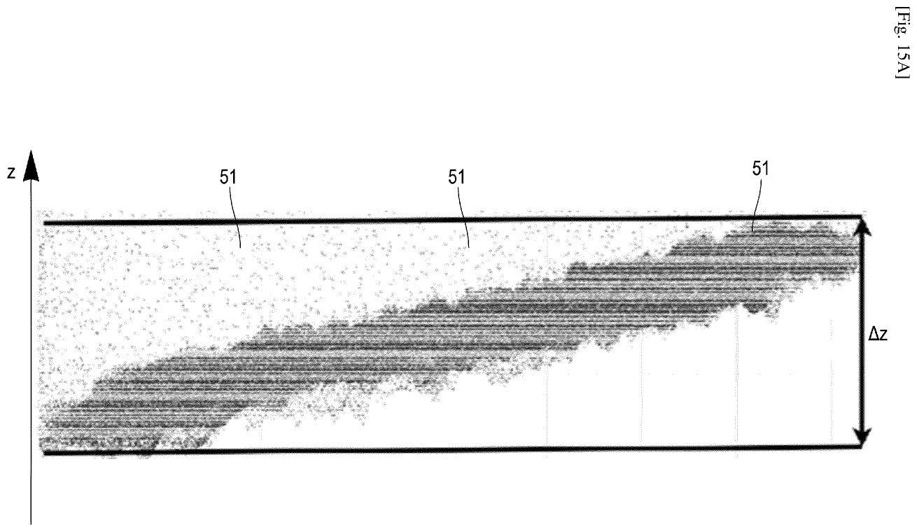

In step 104 there are further specified disjoint sectors 201 of the space in the system of cartesian coordinates (x, y, z). In concrete terms, these sectors 201 are defined by an increment δx of coordinates x and by an increment δy of coordinates y (cf. FIG. 14). Like the numerical values of the design described hereinabove with reference to step 101, the increments δx and δy can be specified by a user, for example by means of a computer-implemented user interface. Alternatively, the design can also have been specified in advance in the form of a file of parameters, possibly editable by the user. The increments δx and δy can be specified a priori thanks to knowing the reference value Q₀ of the radius Q described hereinabove. For example, the increments δx and δy can be specified so that a surface area of the bottom supporting wall 15 included in a given sector 201 is between 5 cm² and 50 cm². In step 105, still with reference to FIG. 14, a discretization point 251 is calculated for each sector 201. Each sector 201 is associated with a range of cartesian coordinates {X±δx/2, Y±δy/2}. The discretization point 251 is the center of the sector 201. Its cartesian coordinates are {X, Y, Z}, where Z is the mean of the coordinates z of all the measurements 51 situated in the sector 201.

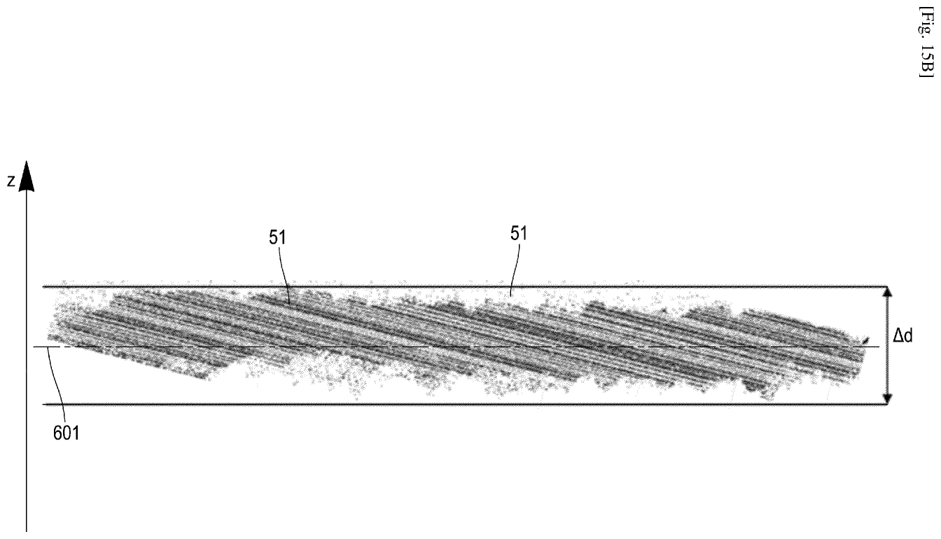

In step 108 a dispersion Δz of the measurements 51 along the vertical axis z is calculated; in other words, the difference is calculated between the highest coordinate z and the lowest coordinate z of the measurements 51. Referring to FIG. 15A, which is a graph representing a statistical distribution of the coordinates z of the measurements 51 in one example, it is clear that the higher Δz the higher the highest asperity of the bottom supporting wall 15. Δz is therefore a parameter that quantifies the non-flatness of the bottom supporting wall 15. Still in step 108, Δz is compared with an acceptable range of non-flatness of the bottom supporting wall 15 specified beforehand in step 101.

In step 108 a global interpolation plane 601 is also calculated on the basis of all the measurements 51 (cf. FIG. 15B). The two measurements 51 farthest from the plane 601 parallel to the vertical axis z are then looked for, one in the positive direction of the vertical axis z and the other in the negative direction of the axis z, and the difference Δd between the coordinates z of these two measurements 51 is calculated. Referring to FIG. 15B, which is a graph representing a statistical distribution of the coordinates z of the measurements 51 in another example, it is clear that in this case Δd quantifies the non-flatness of the bottom supporting wall 15 in a manner different from Δz. Still in step 108, Δd is compared with an acceptable range of non-flatness of the bottom supporting wall 15, which may or may not be identical to that to which Δz is compared.

Alternatively, only one of the dispersions Δz or Δd can be calculated.

The dispersion Δz can advantageously be calculated only on the basis of the measurements 51 that are situated sufficiently far from the vertical supporting panels 14. In more concrete terms, thanks to the a priori knowledge of the reference value Q₀ of the radius Q it is possible to exclude from the calculation of the dispersion Δz the measurements 51 of which the cylindrical coordinate r satisfies r>R₀−R₂ where R₂ is a predetermined threshold. The same advantageously applies to the dispersion Δd. This can make it possible to prevent the evaluation of the non-flatness of the bottom supporting wall 15 taking into account the connection between the bottom supporting wall 15 and the vertical supporting panels 14, especially if that connection takes the form of a chamfer.

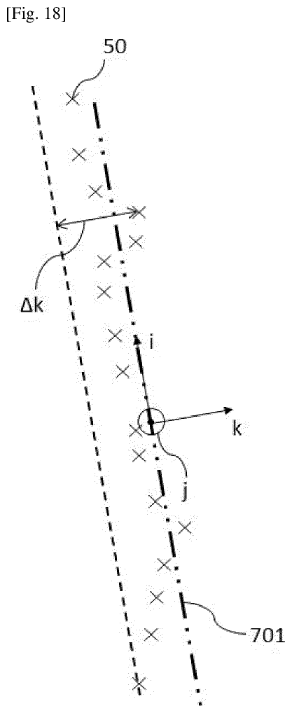

An analogous comparison with an acceptable range of non-flatness of the vertical supporting panels 14 can further be effected in step 108. From the estimated positions 300 of the vertical edges 13 calculated in step 106 there are selected all of the measurements 50 corresponding to a given vertical supporting panel 14 and a global interpolation plane 701 (cf. FIG. 18) is calculated from the selected measurements 50. Note that the global interpolation plane 701 is not necessarily parallel to the local interpolation plane 600 represented in FIG. 13B. The global interpolation plane 701 is then associated with an orthogonal cartesian marker (i, j, k) that is defined in the following manner: the axis (k) is orthogonal to the plane 701 and the axes (i) and (j) are included in the plane 701. Still with reference to FIG. 18, among the measurements 50 used to calculate the plane 701 the two measurements 50 are looked for farthest from the plane 701 parallel to the axis (k), one in the positive direction of the axis (k) and the other in the negative direction of the axis (k), and the difference Δk between the coordinates k of these two measurements 50 is calculated. Still in step 108, Δk is compared with an acceptable range of non-flatness of the vertical supporting panels 14, specified beforehand in step 101. It will be clear that, in a manner analogous to Δd, Δk quantifies the non-flatness of the vertical supporting panel 14. Furthermore, it is clear that Δk may be calculated and compared with the acceptable range of non-flatness of the vertical supporting panels 14 for one of, some of or all of the vertical supporting panels 14.

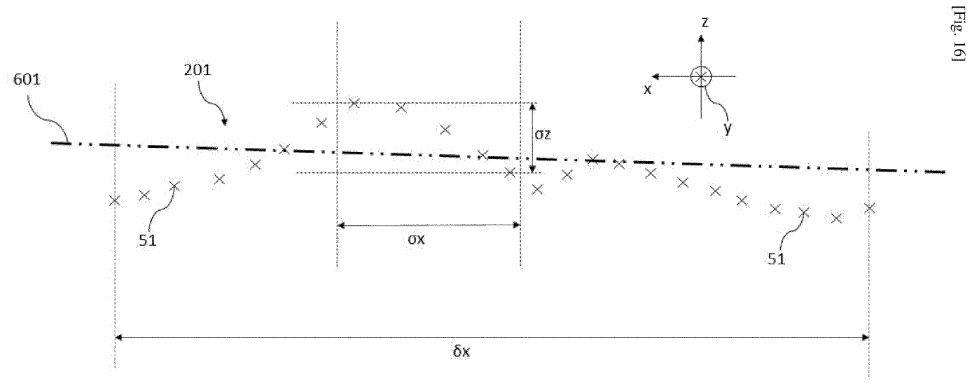

The global interpolation plane 601 may be used to monitor local deformations of the bottom supporting wall 15 as described with reference to FIG. 16. For a given sector 201, a value δx having been specified, the measurements 51 the coordinates x of which are included in an interval of width δx are looked for (cf. FIG. 16); among these measurements 51 in the sector 201 the two measurements 51 farthest from the plane 601 parallel to the vertical axis z are looked for, one in the positive direction of the vertical axis z and the other in the negative direction of the axis z, a difference δz is calculated between the coordinates along the vertical axis z of these two measurements 51, and this difference δz is compared with an acceptable range of local deformations of the bottom wall specified beforehand in step 101. This process is repeated until the sector 201 is exhausted, each time shifting the interval of width δx by a fixed increment; in other words, the interval of width δx is used as a sliding window which can be of any width along the axis y of the system of cartesian coordinates (x, y, z). The foregoing operations are repeated for each of the sectors 201. Alternatively, the two measurements 51 used to calculate δz can be the two measurements farthest from the local interpolation plane that is calculated from all of the measurements 51 included in the sector 201. Note that this local interpolation plane is not necessarily parallel to the global interpolation plane 601.

The principles described hereinabove for a plane bottom supporting wall 15 are equally applicable to a plane lid wall of the supporting structure 10.

The geometry monitoring method described hereinabove can be applied to any civil engineering structure or any welded structure that has to be constructed in accordance with the specified design.

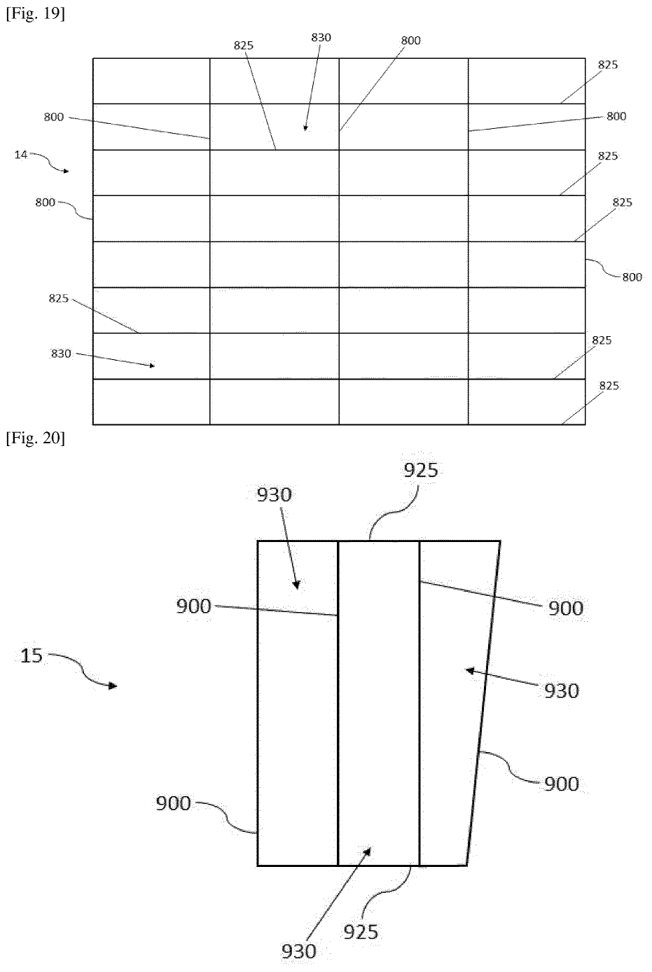

As mentioned hereinabove, the vertical peripheral wall 22 can be formed of vertical rows of plane insulating wall modules and vertical rows of corner insulating wall modules as described in WO 2022/200536 A1 or WO 2022/200539 A1. As described in those documents, knowing the positions in three dimensions of the N vertical edges 13 makes it possible to trace out on the vertical supporting panels 14 vertical marker lines usable for positioning on the vertical supporting panels 14 the vertical rows of plane insulating wall modules and the vertical rows of corner insulating wall modules. In FIG. 19 there have been schematically represented by way of explanation, for a vertical supporting panel 14, vertical marker lines 800 of this kind, together with orthoradial marker lines 825. Referring to FIG. 19, the vertical marker lines 800 and the orthoradial marker lines 825 together delimit disjoint sectors 830, each sector 830 corresponding to the intended location on the vertical supporting panel 14 of a plane insulating wall module or a corner insulating wall module.

In accordance with a variant of the method 100:
the positions of the vertical marker lines 800 are calculated on the basis of the estimated positions 300 of the N vertical edges 13 calculated in step 106 and the measurements 50, as described in WO 2022/200536 A1 or WO 2022/200539 A1;
the positions of the orthoradial marker lines 825 are also calculated, on the basis of the calculated positions of the vertical marker lines 800 and the intended dimensions of the insulating modules; and
in step 108 local deformations of the vertical supporting panels 14 are compared with the acceptable range of local deformations of the vertical supporting panels 14 as described hereinabove, except that, in place of the sectors 200, the sectors 830 are used or sectors having a predetermined radius around the geometric center of each sector 830.

In this way the comparison of the local deformations of the vertical supporting panels 14 with the acceptable range of local deformations of the vertical supporting panels 14 is more indicative of corrective actions to be undertaken on the vertical supporting wall 12 for the plane insulating wall modules and the corner insulating wall modules to be positionable as required on the vertical supporting panels 14.

As described in WO 2022/200536 A1 or WO 2022/200539 A1, the known positions in three dimensions of the N vertical edges 13 further enable tracing out on the plane bottom supporting wall 15 of horizontal marker lines usable to position the angular sectors that are images of one another by rotation and the insulating blocks forming those angular sectors. In FIG. 20 there have been schematically represented by way of explanation such horizontal marker lines 900 together with orthoradial marker lines 925. Referring to FIG. 20, the horizontal marker lines and the orthoradial marker lines 925 together delimit disjoint sectors 930, each sector 930 corresponding to the intended location on the bottom supporting wall 15 of an insulating block. Note that the sectors 930 can be various shapes, notably rectangular, trapezoidal, etc. FIG. 20 is therefore in no way limiting on the invention in this regard.

In accordance with a variant of the method 100:
the positions of the horizontal marker lines 900 are calculated on the basis of the calculated positions of the vertical markers 800, as described in WO 2022/200536 A1 or WO 2022/200539 A1;
the positions of the orthoradial marker lines 925 are also calculated, on the basis of the calculated positions of the horizontal marker lines 900 and the intended dimensions of the insulating blocks; and
in step 108 local deformations of the plane bottom supporting wall 15 are compared with the acceptable range of local deformations of the bottom supporting wall as described hereinabove, except that instead of the sectors 201 the sectors 930 are used or sectors having a predetermined radius around the geometric center of each sector 930.

In this way comparison of the local deformations of the plane bottom supporting wall 15 with the acceptable range of local deformations of the bottom supporting wall is more indicative of corrective actions to be undertaken on the vertical supporting wall 12 so that the insulating blocks can be positioned as required on the bottom supporting wall 15.

Since the sectors 830, 930 correspond to the intended location of the insulating wall modules or insulating blocks, the measurements 50, 51 included in the sectors 830, 930 can further be used to calculate the dimensions of spacing elements. For example, the spacing elements comprise shims and/or beads of mastic. The spacing elements are intended to correct flatness defects of the vertical supporting panels 14 and the bottom supporting wall 15. To this end the spacing elements are positioned between an insulating wall module and a vertical supporting panel 14 or between an insulating block and the bottom supporting wall 15. The dimensions of the spacing elements can be calculated as described in WO 2023/073201 A1 for example.

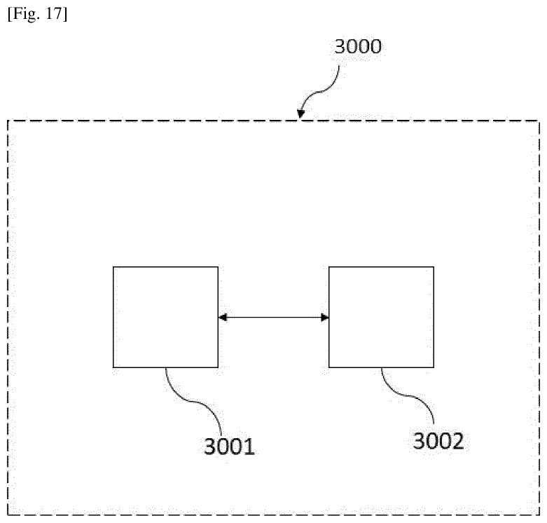

The geometry monitoring methods described hereinabove can be implemented by means of a geometry monitoring device 3000 (cf. FIG. 17). The geometry monitoring device 3000 comprises at least one processor 3001 and at least one memory 3002 containing a computer program; the at least one memory 3002 and the computer program are configured, with said at least one processor 3001, to implement the geometry monitoring method 100 described above. The geometry monitoring device 300 can take various unitary or distributed forms employing hardware and/or software components. Usable hardware components include application-specific integrated circuits (ASIC), field-programmable gate arrays (FPGA) and microprocessors. Software components can be written in various programming languages, for example C, C++, Java (registered trade mark) or VHDL. This list is not exhaustive.

Although the invention has been described with reference to a plurality of particular embodiments it is obvious that it is in no way limited to them and that it encompasses all technical equivalents of the means described and combinations thereof that fall within the scope of the invention.

Use of the verb “include” or “comprise” and conjugate forms thereof does not exclude the presence of elements or steps other than those stated in a claim.

In the claims, any reference sign between parentheses should not be interpreted as a limitation of the claim.

1. A computer-implemented geometry monitoring method (100) comprising:
specifying (101) a structure design (10), the structure design (10) having geometric attributes and dimensional attributes, the geometric attributes including a number N of sides of a polygon, N being an integer greater than or equal to 3, the dimensional attributes including an acceptable range of diameters (D);
obtaining (102) a plurality of first measurements (50) each representing a measured position in a three-dimensional frame of reference (x₁, y₁, z₁) of a point situated on a structure to be monitored;
determining (103) a system of cylindrical coordinates (r, θ, z) having a vertical axis (19) parallel to an axis of said three-dimensional frame of reference, said vertical axis (19) having a position that minimizes a dispersion of said first measurements (50) with respect to a radial coordinate (r) of said system of cylindrical coordinates;
specifying (104) first disjoint sectors (200) of the space in the system of cylindrical coordinates (r, θ, z), said first sectors (200) being defined by azimuth coordinate increments (80) and axial coordinate increments (δz) in said system of cylindrical coordinates (r, θ, z);
calculating (105) on the basis of the first measurements (50) a plurality of first discretization points (250), each first discretization point (250) representing a mean position of the structure to be monitored in one of said first sectors (200);
calculating (106) on the basis of the first discretization points (250) estimated positions (300) of N vertical edges (13) of the structure to be monitored;
calculating (107) on the basis of the estimated positions (300) of the N vertical edges (13) estimated positions (400) of N medians, each median being a median of the vertical panel (14) of the structure to be monitored; and
comparing (108) on the basis of the estimated positions of the N medians the distances between diametrically opposite medians and an acceptable range of diameters (D).

2. The geometry monitoring method (100) as claimed in claim 1, in which the dimensional attributes further include an acceptable range of radii (Q) and in which the geometry monitoring method (100) further comprises comparing (108) the distances between said estimated positions (400) of the N medians and said vertical axis (19) with said acceptable range of radii.

3. The geometry monitoring method (100) as claimed in claim 1, in which the dimensional attributes further include an acceptable range of panel widths (W) and in which the geometry monitoring method (100) further comprises comparing (108) the distances between the estimated positions (300) of two adjacent vertical edges (13) with said acceptable range of panel widths.

4. The geometry monitoring method (100) as claimed in claim 1, in which the dimensional attributes further include an acceptable range of edge non-verticality (NV) and in which the geometry monitoring method (100) further comprises comparing (108) distances perpendicular to the vertical axis (19) of said system of cylindrical coordinates between end points of each vertical edge (13) with said acceptable range of edge non-verticality (NV).

5. The geometry monitoring method (100) as claimed in claim 1, in which the dimensional attributes further include an acceptable range of ovalization (OV) and in which the geometry monitoring method (100) further comprises comparing (108) a diameter difference between an inscribed larger circle (CI) of the vertical wall (12) and a circumscribed smaller circle (CC) of the vertical wall (12) of the structure to be monitored with said acceptable range of ovalization.

6. The geometry monitoring method (100) as claimed in claim 1, in which the dimensional attributes further include an acceptable range of local deformations of the vertical panels (14) and in which the geometry monitoring method (100) further comprises comparing local deformations of the structure to be monitored with said acceptable range of local deformations of the vertical panels (14).

7. The geometry monitoring method (100) as claimed in claim 1, in which the dimensional attributes further include an acceptable range of non-verticality of the vertical panels (14) and in which the geometry monitoring method (100) further comprises:
selecting a subset of the first discretization points (250), in which subset the azimuth coordinates (Θ) of the first discretization points (250) are equal to one another;
determining the differences (AR) of radial coordinates (R) between the first discretization points (250) of the subsets; and
comparing the differences (ΔR) of radial coordinates (R) with said acceptable range of non-verticality of the vertical panels (14).

8. The geometry monitoring method (100) as claimed in claim 1, in which the dimensional attributes further include an acceptable range of non-flatness of the vertical panels (14) and the geometry monitoring method (100) further includes:
on the basis of the estimated positions (300) of the N vertical edges (13), selecting the first measurements (50) corresponding to a vertical panel (14) of the structure to be monitored;
calculating a vertical panel non-flatness parameter (Δk) on the basis of the selected first measurements (50) and comparing the vertical panel non-flatness parameter (Δk) with said acceptable range of non-flatness of the vertical panels (14).

9. The geometry monitoring method (100) as claimed in claim 1, in which the geometric attributes further include a plane bottom wall and the dimensional attributes further include an acceptable range of non-flatness of the bottom wall, and the geometry monitoring method (100) further includes:
obtaining (102) a plurality of second measurements (51) each representing a position measured in said three-dimensional frame of reference (x₁, y₁, z₁) of a point situated on a bottom wall (15) of the structure to be monitored;
associating (103) with the second measurements (51) a system of cartesian coordinates (x, y, z), said system of cartesian coordinates having a first axis, a second axis and a third axis that are mutually perpendicular, the third axis coinciding with said vertical axis (19) of said system of cylindrical coordinates;
specifying (104) disjoint second sectors (201) of the space in said system of cartesian coordinates, said second sectors (201) being defined by increments (δx, δy) of coordinates along the first axis and the second axis of said system of cartesian coordinates (x, y, z);
calculating (105) on the basis of the second measurements (51) a plurality of second discretization points (251), each second discretization point (251) representing a mean position of the bottom wall (15) of the structure to be monitored in one of said second sectors (201);
calculating (108) a parameter of non-flatness of the bottom wall (Δz; Δd) on the basis of the second discretization points (251) and comparing (108) the parameter of non-flatness of the bottom wall (Δz; Δd) with said acceptable range of non-flatness of the bottom wall.

10. The geometry monitoring method (100) as claimed in claim 9, in which the dimensional attributes further include an acceptable range of local deformations of the bottom wall and in which the geometry monitoring method (100) further comprises comparing local deformations of the bottom wall of the structure to be monitored with said acceptable range of local deformations of the bottom wall.

11. The geometry monitoring method (100) as claimed in claim 1, in which N is an even number and N is more particularly an even number between 8 and 56, even more particularly N=8 or N=56.

12. The geometry monitoring method (100) as claimed in claim 1, further comprising a generation step consisting in generating (109) a visual representation of a result of at least one of said comparisons (108).

13. The geometry monitoring method (100) as claimed in claim 1, further including the step of assigning a qualification of conformity to the structure to be monitored, the qualification of conformity being chosen between conform and non-conform.

14. The geometry monitoring method (100) as claimed in claim 1, in which the plurality of first measurements (50) comes from an acquisition of measurements (1001) by means of a measuring instrument in the structure to be monitored and in which the measuring instrument includes a laser detection and ranging device (91) disposed in an internal space (11) of the structure to be monitored.

15. The geometry monitoring method (100) as claimed in claim 1, in which the structure to be monitored is a supporting structure for a liquefied gas storage installation (1).

16. The geometry monitoring method (100) as claimed in claim 1, in which the structure to be monitored is made of concrete.

17. A computer program comprising instructions which, when the computer program is implemented by a computer, cause the computer to execute the geometry monitoring method (100) as claimed in claim 1.

18. A geometry monitoring device (3000) comprising at least one processor (3001) and at least one memory (3002) containing a computer program, in which said at least one memory (3002) and the computer program are configured, with said at least one processor (3001), to cause execution of the geometry monitoring method (100) as claimed in claim 1 by the geometry monitoring device (3000).
